(19) United States
(12) Patent Application Publication
(10) Pub. No.: US 2005/0020095 A1
(43) Pub. Date: Jan. 27, 2005

(54) Method for surface treating a semiconductor

(76) Inventors: Johannes Baur, Laaber (DE); Georg Bruderl, Burglengenfeld (DE); Alfred Lell, Maxhutte-Haidhof (DE); Walter Neu, Leer (DE); Raimund Oberschmid, Sinzing (DE)

Correspondence Address: COHEN, PONTANI, LIEBERMAN & PAVANE, 551 FIFTH AVENUE, SUITE 1210, NEW YORK, NY, 10176, US

(21) Appl. No.: 10/487,577

(22) PCT Filed: Aug. 14, 2002
(86) PCT No.: PCT/DE02/02981

(30) Foreign Application Priority Data
Aug. 23, 2001 (DE) 101 41 352.1

(51) Int. Cl. H01L 21/26; H01L 21/324; H01L 21/84; H01L 21/00

(52) U.S. Cl. 438/795; 438/796; 438/166

(57) ABSTRACT

The invention relates to a method for the thermal treatment of a surface layer (4) on a semiconductor substrate (5). Laser pulses (2) generated by a laser (1) are emitted onto the surface layer (4). This method can be used to produce, in particular, ohmic contacts to III-V compound semiconductors.

The invention relates to a method in which a surface layer, in particular made of a compound semiconductor material with a band gap of >2.5 eV, having a thickness of between 1 and 150 nm is applied to a semiconductor substrate and subjected to a thermal treatment. It relates in particular to a method for producing radiation-emitting semiconductor components based on compound semiconductor materials, preferably based on III-V compound semiconductor materials.

Such methods for the thermal treatment of surface layers made of a III-V compound semiconductor are known. The III-V compound semiconductors are usually semiconductors based on InP, GaP, GaAs or GaN, that is to say for example semiconductor materials having the general composition AlₓIn_{y}Ga_{1-x-y}P, AlₓGa₁₋ₓAs or AlₓIn_{y}Ga_{1-x-y}N where 0<x<1, 0<y<1 and x+y<1.

A surface layer made of a metal is generally applied to the substrate surface formed by the III-V compound semiconductors. In this case, the surface layer may contain dopants for the underlying III-V compound semiconductor. Afterward, the semiconductor substrate is introduced into a furnace and heated with the aid of a radio frequency source, UV light or heating plate.

The quality of the contacts produced in this way is often unsatisfactory despite the high degree of diffusion of atoms from the surface layer into the semiconductor substrate. U.S. Pat. No. 6,110,813 A discloses a method for surface treatment by means of laser radiation. Given a suitable wavelength of the laser beams, this method affords the advantage that the metal layer is heated selectively since the laser radiation is not absorbed, or is only slightly absorbed, by the substrate made of SiC. This is the case when the photon energy of the laser radiation is smaller than the band gap of the substrate made of SiC.

Taking this prior art as a departure point, the invention is based on the object of specifying an improved method for the thermal treatment of the surface layer.

This object is achieved according to the invention by virtue of the fact that the surface layer is thermally treated with the aid of a laser pulse having a duration of less than or equal to 0.1 μsec and an irradiation energy density of between 10 and 1 000 mJ/cm².

The use of laser pulses having a duration of less than or equal to 0.1 μsec and an irradiation energy density of between 10 and 1 000 mJ/cm² means that only the material directly under the irradiated surface is heated. On account of the high irradiation energy density, the temperature in the surface layer reaches a high maximum value, which generally lies above 1 000° C., toward the end of the laser pulse and then falls rapidly typically on a time scale of <1 μsec. The thermal diffusion front penetrating into the interior of the semiconductor substrate also already falls to a fraction of the maximum value of the temperature in the depths of a few μm. Therefore, in the method according to the invention, only a thin layer below the irradiated surface is heated, while the rest of the semiconductor substrate experiences only a slight increase in temperature. Consequently, the method according to the invention makes it possible to carry out the thermal treatment locally in a targeted manner without the need to heat the entire semiconductor substrate. Therefore, the probability of the structure or the composition of the semiconductor substrate being disadvantageously altered by the thermal treatment of the surface layer is low in the case of the method according to the invention. In particular, there is no need to fear any indiffusion of dopants or other contaminants into an active zone or an increase or else undesirable reduction of lattice strains. In particular, in the material system AlₓIn_{y}Ga_{1-x-y}N, it is possible to prevent the formation of N-type vacancies acting as donors, through which the doping level of the p-type doping in the semiconductor substrate is lowered.

In one advantageous embodiment of the method, laser pulses are applied to the surface of the surface layer locally according to a predetermined pattern.

On account of the rapid fall of the thermal diffusion front, it is possible for the surface layer also to be heated locally in the lateral direction. This property can be used locally to increase or decrease the resistance between the surface layer and the semiconductor substrate, as required, in order, by way of example, to feed current in a targeted manner into an active zone formed in the semiconductor substrate.

The dependent claims relate to advantageous developments and embodiments.

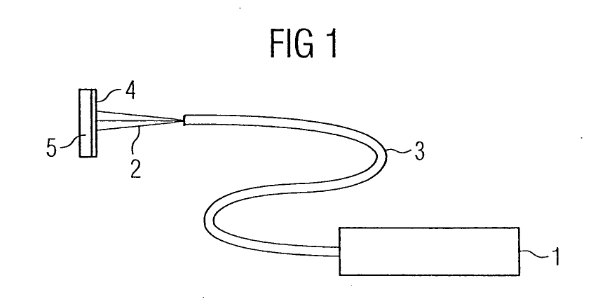

Further advantages of the invention and advantageous embodiments emerge from the exemplary embodiment explained below in conjunction with FIGS. 1 to 3, in which:

FIG. 1 shows a diagrammatic illustration of an apparatus for carrying out the method;

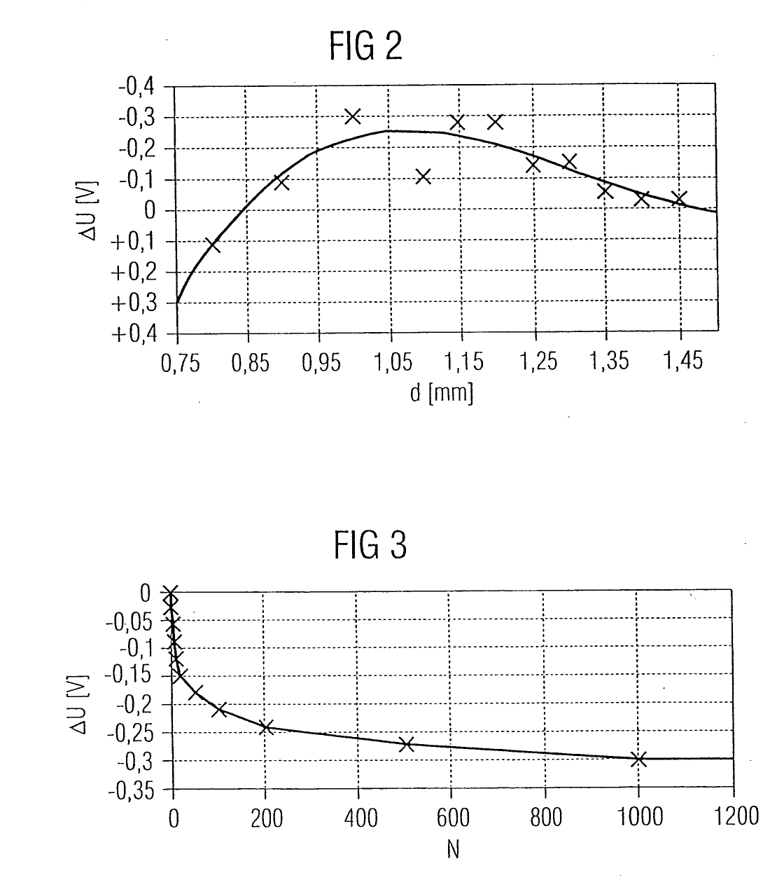

FIG. 2 shows a diagram showing the change in the forward voltage of a light-emitting diode as a function of the irradiation energy density of the laser pulses; and

FIG. 3 shows a diagram showing the dependence of the forward voltage of a light-emitting diode on the number of laser pulses impinging on a surface layer.

In order to carry out the method, it is possible, by way of example, as illustrated in FIG. 1, to use a laser 1 whose laser radiation 2 is coupled into an optical fiber 3 and directed onto a surface layer 4 on a semiconductor substrate 5 with the aid of the optical fiber 3.

In this connection, the semiconductor substrate 5 is as not only a single-crystal slice of a specific composition but also, by way of example, a slice comprising a monocrystalline substrate wafer on which a layer sequence is applied. The semiconductor substrate may be, by way of example, a layer sequence for functional semiconductor chips for a light-emitting diode.

In this connection, the surface layer 4 is to be understood as a layer applied to the semiconductor substrate 5. What may be involved in this case is, in particular, a contact layer which serves for producing an ohmic contact between a lead provided at the contact layer and the semiconductor substrate.

The apparatus illustrated in FIG. 1 generates a pulsed laser radiation. By virtue of a laser pulse having a duration of less than 0.1 μsec., preferably less than 1 nsec, and having a high irradiation energy density of between 10 and 1 000 mJ/cm², the temperature in the surface layer 4, having a thickness of between 1 and 150 nm, reaches a maximum value of above 1000° C. and then falls rapidly with a time scale of less than 1 μsec. The thermal diffusion front penetrating into the interior of the semiconductor substrate 5 also already decreases to a fraction of the outer maximum value for the temperature in a depth of a few μm. In this case, the following holds true for the thickness d of the heated volume below the irradiated area:
d=\sqrt{DΔt}
where Δt is the pulse duration of the laser pulse and D is the diffusivity.

The diffusivity D results from the thermal conductivity λ divided by the specific volume heat capacity Cᵥ and is typically of the order of magnitude of 0.5 to 2 cm² sec for most semiconductor materials.

The maximum value for the temperature is identical in terms of order of magnitude:

$${T}_{max} = \frac{E}{{C}_{v} d}$$

where E is the irradiation energy density in Wcm² and d is the thickness of the heated volume. The specific volume heat capacity Cᵥ is about 1.5 J/Kcm³ for semiconductors.

In accordance with these formulae, a laser pulse of UV light having a length of 0.1 nsec only heats a volume having a thickness of 150 nm under the irradiated surface. In this case, temperatures of about 1 500° C. are achieved in the case of an irradiation energy density of the pulses of about 50 mJ/cm².

Consequently, through the pulse duration it is possible to define the thickness of the heated volume in a targeted manner, while the maximum value of the temperature achieved in the volume can be set by way of the irradiation energy density.

With this method, by way of example, the Schottky contact barrier can be decreased or increased depending on the irradiation energy density and duration of the. laser pulses.

In FIG. 2, by way of example, the change (ΔU) in the forward voltage U_{f} in the case of a semiconductor substrate 5 for a light-emitting diode is plotted as a function of the distance d between the end of the optical fiber 3 and the contact layer 4.

In order to carry out the experiment, a semiconductor substrate which had epitaxial layers based on GaN was selected for a light-emitting diode. The epitaxial layers comprised a pn junction. On the p-type side, the light-emitting diode was provided with the surface layer 4 in the form of platinum contacts. The platinum contacts had a diameter of 200 μm and a thickness of 8 nm. Said platinum contacts were contact-connected and loaded with a forward current of 20 mA. At the same time, the voltage difference between the platinum contacts and the semiconductor substrate 5 was measured using an electrometer. In this case, the voltage difference was measured before and after the irradiation of the surface of the surface layer 4 with laser pulses. The measurements were repeated in each case for different distances d between the optical fiber 3 and the surface of the surface layer 4, in order to vary the irradiation energy density E. The laser pulses are laser pulses having a duration of 1 nsec, 100 laser pulses having been emitted in series with a frequency of 10 Hz onto the surface layer 4.

The results of the measurements are contained in table 1 and in FIG. 2. ΔU designates the change in the voltage difference in volts between the platinum contact and the semiconductor substrate as a result of the irradiation with laser pulses.

| d (mm) | ΔU (V) |
|---|---|
| 0.80 | +0.11 |
| 0.90 | −0.09 |
| 1.00 | −0.30 |
| 1.10 | −0.11 |
| 1.15 | −0.28 |
| 1.20 | −0.28 |
| 1.25 | −0.14 |
| 1.30 | −0.15 |
| 1.35 | −0.06 |
| 1.40 | −0.03 |
| 1.45 | −0.03 |

The semiconductor substrate measured had a forward voltage of 3.95 V before the measurements and subsequently had a forward voltage U_{f} of 3.65 V after the measurements in the most favorable case corresponding to a voltage change of 0.3 V.

The forward voltage deteriorates in the case of a distance of less than 0.85 mm. This is attributed to damage to the active zone of the p-doped semiconductor region or the platinum contacts.

By contrast, the lowering of the forward voltage U_{f}, which corresponds to an improvement of the ohmic contact between the surface layer 4 and the semiconductor substrate 5, may be based either on an activation of the dopants in a region of the epitaxial layers of the semiconductor substrate 5 that is adjacent to the surface layer 4, or on alloying of the platinum contact with the semiconductor material near the surface. The activation of the dopants in a region near the surface to be effected with a maximum distance of less than 1 μm. The alloying of the metal of the surface layer 4 with the semiconductor substrate is effected as far as a depth of more than 10 nm, but less than 1 μm.

Also of interest is the behavior of the forward voltage as a function of the number of pulses. In FIG. 3, the change ΔU in the forward voltage U_{f} is plotted as a function of the number N of laser pulses. This measurement was recorded given a distance d of 1.3 mm. FIG. 3 reveals that the voltage may already be lowered by 0.03 V with the first laser pulse. Afterward, two laser pulses are already necessary in order to achieve the same result, then five and in the next step ten. No further reduction of the forward voltage is measurable after about 1 000 laser pulses.

The surface layer 5 thus treated also exhibits a stable aging behavior. Specifically, no or only a very slight impairment of between 0.01 and 0.03 V was manifested in the course of a few weeks.

What is particularly advantageous is that a reduction of the p-type doping of layers made of AlₓI_{ny}Ga_{1-x-y}N through to doping reversal can be carried out by the method described. A lateral delimitation of the current impression is possible in this way. By way of example, it is possible to pattern the surface layer 4 by means of an etching method, so that the p-type doping of those regions of the semiconductor substrate 5 which are protected by the surface layer 4 is increased, while the unprotected regions of the semiconductor substrate have a reduced p-type conductivity on account of the heating of the top side and the resultant production of n-type vacancies.

In particular, metal containing Mg or Zn is suitable for such a surface layer 5 which simultaneously serves as a mask.

The lateral delimitation of the current impression is possible in particular in the case of III-V compound semiconductors based on AlₓIn_{y}Ga_{1-x-y}N.

A series of further aspects of the invention are presented below.

As already mentioned, pulse sequences of laser pulse can be directed onto the semiconductor substrate 5 through the optical fiber 3. The number of pulses should be between 2 and 100 and the time interval between the individual laser pulses should amount to more than ten thousand times the pulse duration in order to ensure that the surface layer 4 has enough time for cooling.

It is furthermore possible, when applying the method to a wafer, to direct the laser radiation onto the wafer in a spatial pattern rather than uniformly. The pattern may be realized for example with the aid of a perforated screen mask. This pattern generally corresponds to the later chip grid dimension.

It is also conceivable to employ a wafer stepper method in which firstly a spatially delimited excerpt from the wafer is irradiated with the laser pulses and then after a spatial displacement of the wafer, a further excerpt from the wafer is irradiated, so that finally the entire wafer is irradiated uniformly with laser pulses. In this case, the areas exposed to laser pulses should as far as possible lie in the chip grid.

If the intention is to prevent current from being fed into the semiconductor substrate 5, in particular into the active zone of the semiconductor substrate 5, below the contact point provided for the bonding of the contact wire, the area provided for the contact point may be irradiated in a targeted manner, the pulse duration and the irradiation energy density being chosen in such a way as to impair the electrical contact properties between the surface layer 4 and the semiconductor substrate 5.

Conversely, it is also possible for the edges of the areas provided for the contact point to be irradiated in a targeted manner in order to improve the current transfer at the edges of the contact point. If the contact point is formed in circular fashion, it is advantageous, for example, to improve the ohmic contact annularly around the contact point. In order that the change of the ohmic contact between the surface layer 5 and the semiconductor substrate can be carried out in a targeted manner, the irradiation with laser pulses can be carried out in a targeted manner after a measurement of the chip properties, in order to trim the chips to a desired value. In this case, the parameters of the laser pulses, such as irradiation energy density, laser pulse duration and number of laser pulses, are expediently set or regulated in accordance with the initial or interim measurement results.

It may also be advantageous to irradiate the surface of the semiconductor substrate with laser pulses even before the application of the surface layer 4 on the semiconductor substrate 5, in order to influence the mechanical adhesion properties or to activate dopants that have already been introduced into the semiconductor substrate 5, or in order to support the short range diffusion of said dopants.

In order to weaken or strengthen the doping of the semiconductor substrate 5, the surface layer 4 may contain donors or acceptors.

After the conclusion of the irradiation with laser pulses, a further contact layer may be applied to the surface layer 4 and a bonding wire may be provided at the contact layer.

It is also conceivable to deposit a passivation layer made of Al₂O₃ or SiOₓN_{y}, where 0<x<2, 0<y<1, on the surface layer irradiated with laser pulses or the contact layer.

The method described here makes it possible to influence the conductivity properties of the semiconductor layers in the vicinity of a surface both in the lateral direction and in the transverse direction. The method can be applied to III-V compound semiconductors. The method can be applied particularly advantageously to materials having the composition AlInGaN.

1. A method for the thermal treatment of a surface layer (4) on a semiconductor substrate (5), characterized in that the surface layer (4) is thermally treated with the aid of a laser pulse having a duration of <0.1 μsec and an irradiation energy density of between 10 and 1 000 mJ/cm².

2. The method as claimed in claim 1, in which the semiconductor substrate (5) comprises a III-V compound semiconductor material with a band gap of >2.5 eV and the surface layer (4) has, in particular, a thickness of between 1 and 150 nm.

3. The method as claimed in claim 1 or 2, in which the surface layer (4) comprises donors or acceptors.

4. The method as claimed in claim 1 or 2, in which the surface layer (4) is produced from a metal.

5. The method as claimed in claim 4, in which the surface layer (4) is produced from a material with at least one element from the group Pt, Mg, Zn with in each case a proportion of >0.01% by weight.

6. The method as claimed in one of claims 1 to 5, in which the semiconductor substrate (5) is produced at least partly from a III-V compound semiconductor.

7. The method as claimed in claim 6, in which the semiconductor substrate (5) is produced at least partly from AlₓIn_{y}Ga_{1-x-y}N where 0≦x≦1, 0≦y≦1 and x+y≦1.

8. The method as claimed in one of claims 1 to 7, in which a laser pulse having a duration of <1 nsec is used.

9. The method as claimed in one of claims 1 to 8, in which laser radiation having a wavelength of <450 nm is used for the laser pulse.

10. The method as claimed in one of claims 1 to 9, in which the surface layer (4) is melted by the laser pulse.

11. The method as claimed in one of claims 1 to 10, in which a sequence of laser pulses is emitted onto the surface layer (4).

12. The method as claimed in claim 11, in which the laser pulses are emitted at a time interval which is greater than ten thousand times the pulse duration of the laser pulses.

13. The method as claimed in one of claims 1 to 12, in which laser pulses are applied to the semiconductor substrate (5) in a predetermined pattern with the aid of a mask.

14. The method as claimed in one of claims 1 to 13, in which the semiconductor substrate (5) is spatially displaced between two laser pulses.

15. The method as claimed in one of claims 1 to 14, in which laser pulses are applied to the edges of the areas provided for contacts on the surface layer (4).

16. The method as claimed in one of claims 1 to 14, in which laser pulses are applied to the areas of the surface layer (4) which are provided for contacts.

17. The method as claimed in one of claims 1 to 16, in which laser pulses are applied to the surface layer (4) after a measurement of components formed in the semiconductor substrate (5) for the purpose of influencing the measured parameters.

18. The method as claimed in one of claims 1 to 17, in which a further reinforcement layer is applied to the surface layer (4).

19. The method as claimed in claim 18, in which the reinforcement layer contains at least one element from the group Zn and Mg.

20. The method as claimed in one of claims 1 to 19, in which a passivation layer made of Al₂O₃, or SiOₓN_{y} where 0<x≦2, 0≦y≦1, is subsequently arranged on a side of the surface layer facing away from the substrate.

21. The method as claimed in one of claims 1 to 20, in which the surface of the semiconductor substrate (5) is irradiated with laser pulses before the application of the surface layer (4) on the semiconductor substrate (5).
